(19) United States
(12) Patent Application Publication
(10) Pub. No.: US 2026/0088817 A1
(43) Pub. Date: Mar. 26, 2026

(54) SEMICONDUCTOR ELEMENT DRIVING CIRCUIT

(71) Applicant: Mitsubishi Electric Corporation, Tokyo (JP)

(72) Inventor: Jun FUKUDOME, Tokyo (JP)

(73) Assignee: Mitsubishi Electric Corporation, Tokyo (JP)

(21) Appl. No.: 19/230,242

(22) Filed: Jun. 6, 2025

(30) Foreign Application Priority Data
Sep. 20, 2024 (JP) 2024-163656

(51) Int. Cl. H03K 17/687; H03K 17/567

(52) U.S. Cl. CPC H03K 17/6872; H03K 17/567

(57) ABSTRACT

A semiconductor element driving circuit includes: a first output terminal to which a first power semiconductor element is connected; a second output terminal to which a second power semiconductor element having a lower threshold voltage than the first power semiconductor element is connected; a first cutoff semiconductor element that reduces a voltage of the first output terminal when turned on; a second cutoff semiconductor element that reduces a voltage of the second output terminal when turned on; and a cutoff control circuit that turns on the first cutoff semiconductor element and the second cutoff semiconductor element via a cutoff pre-stage circuit.

### BACKGROUND

### Technical Field

The present disclosure relates to a semiconductor element driving circuit.

### Description of the Background Art

A semiconductor element driving circuit that drives two power semiconductor elements connected in parallel has been proposed (for example, Japanese Patent Application Laid-Open No. 2018-198505).

In a semiconductor device including two power semiconductor elements connected in parallel, it is required to reduce the conduction loss by improving characteristics of one power semiconductor element and to reduce the cost by downsizing a chip of one power semiconductor element. As one configuration that satisfies the requirements, a configuration has been proposed in which a threshold voltage of one power semiconductor element is lowered. However, in an inverter apparatus including two power semiconductor elements as an own arm, when an opposing arm connected in series with the own arm performs switching, the voltage between a collector and an emitter (between a drain and a source) of the two power semiconductor elements of the own arm steeply increases.

As a result, the gate capacitance of the power semiconductor elements of the own arm is charged by a displacement current generated by a temporal change (dV/dt) of the voltage, and thus floating of the gate voltage occurs, in which the gate voltage hardly decreases. As a result, there is a problem that malfunction may occur in which a power semiconductor element (particularly, a power semiconductor element having a low threshold voltage) is turned on even when the power semiconductor element is to be turned off.

### SUMMARY

The present disclosure has been made in view of the above problem, and an object thereof is to provide a technique capable of suppressing malfunction of a power semiconductor element.

A semiconductor element driving circuit according to the present disclosure includes: an input terminal; a first output terminal to which a first power semiconductor element is connected; a second output terminal to which a second power semiconductor element connected in parallel with the first power semiconductor element and having a lower threshold voltage than the first power semiconductor element is connected; a first output pre-stage circuit that generates a first input correspondence signal on the basis of an input signal of the input terminal; a first output circuit that drives the first power semiconductor element via the first output terminal on the basis of the first input correspondence signal; a first cutoff semiconductor element that reduces a voltage of the first output terminal when turned on; a second output pre-stage circuit that generates a second input correspondence signal on the basis of the input signal; a second output circuit that drives the second power semiconductor element via the second output terminal on the basis of the second input correspondence signal; a second cutoff semiconductor element that reduces a voltage of the second output terminal when turned on; a cutoff pre-stage circuit that is connected to the first cutoff semiconductor element and the second cutoff semiconductor element; and a cutoff control circuit that turns on the first cutoff semiconductor element and the second cutoff semiconductor element via the cutoff pre-stage circuit in a case where the input signal is at a low level and the voltage of the first output terminal is lower than a predetermined value.

It is possible to suppress malfunction of a first power semiconductor element and a second power semiconductor element.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a circuit diagram illustrating a configuration of a semiconductor element driving circuit according to a first preferred embodiment;

FIG. 2 is a timing chart illustrating operation of the semiconductor element driving circuit according to the first preferred embodiment;

FIGS. 3 to 6 are circuit diagrams each illustrating a configuration example of a cutoff control circuit according to the first preferred embodiment;

FIG. 7 is a circuit diagram illustrating a configuration of a semiconductor element driving circuit according to a second preferred embodiment;

FIG. 8 is a timing chart illustrating operation of the semiconductor element driving circuit according to the second preferred embodiment;

FIG. 9 is a circuit diagram illustrating a configuration example of a delay buffer according to the second preferred embodiment;

FIG. 10 is a circuit diagram illustrating a configuration of a semiconductor element driving circuit according to a third preferred embodiment;

FIG. 11 is a timing chart illustrating operation of the semiconductor element driving circuit according to the third preferred embodiment; and

FIG. 12 is a circuit diagram illustrating a configuration of a semiconductor element driving circuit according to a fourth preferred embodiment.

### DESCRIPTION OF THE PREFERRED EMBODIMENTS

Hereinafter, preferred embodiments will be described with reference to the accompanying drawings. Features described in the following preferred embodiments are examples, and all features are not necessarily essential. Furthermore, in the following description, similar components in a plurality of preferred embodiments are denoted by the same or similar reference numerals, and different components will be mainly described.

### First Preferred Embodiment

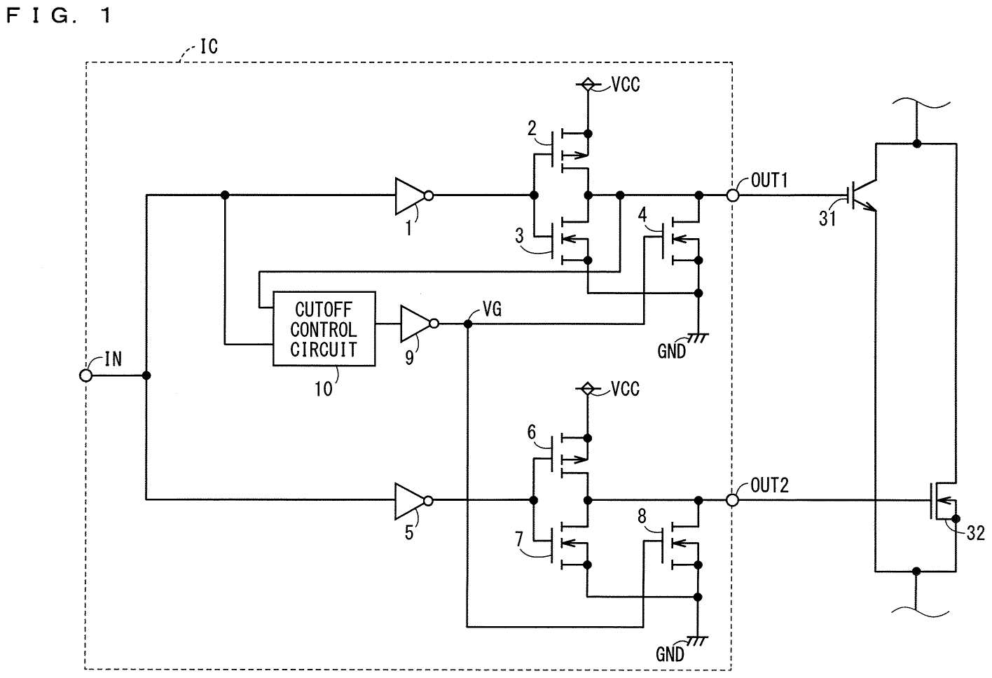

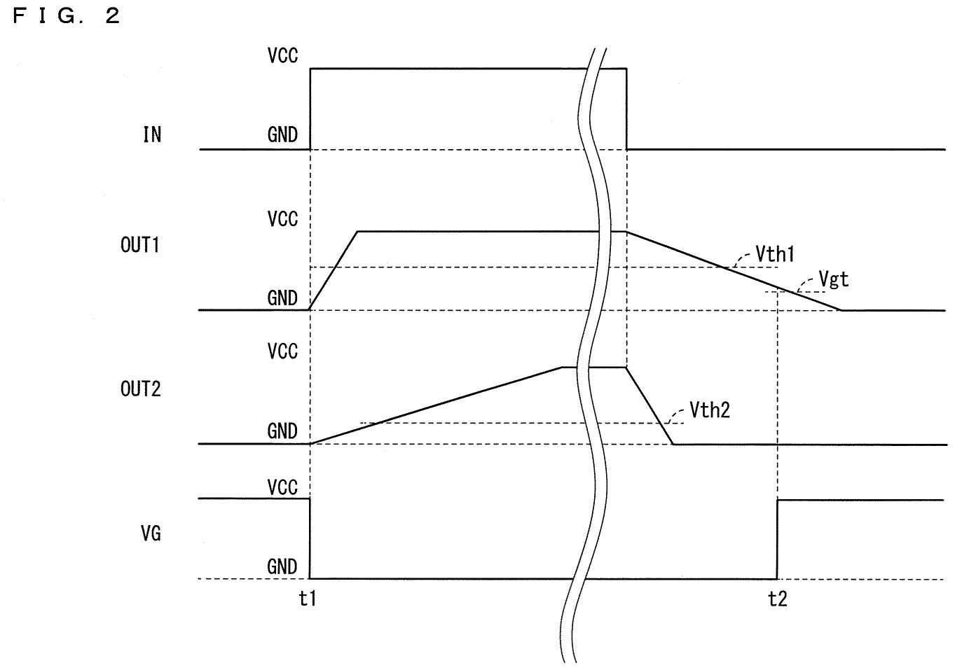

FIG. 1 is a circuit diagram illustrating a configuration of a semiconductor element driving circuit IC according to the first preferred embodiment, and FIG. 2 is a timing chart illustrating an outline of operation of the semiconductor element driving circuit IC.

The semiconductor element driving circuit IC of FIG. 1 includes an input terminal IN, a first output terminal OUT1, a second output terminal OUT2, a first output pre-stage circuit 1, a first output circuit including semiconductor elements 2 and 3, a first cutoff semiconductor element 4, a second output pre-stage circuit 5, a second output circuit including semiconductor elements 6 and 7, a second cutoff semiconductor element 8, a cutoff pre-stage circuit 9, and a cutoff control circuit 10. The semiconductor element driving circuit IC, and a first power semiconductor element 31 and a second power semiconductor element 32 connected to the semiconductor element driving circuit IC are provided in a semiconductor device.

The first output terminal OUT1 is connected to a gate of the first power semiconductor element 31, and the second output terminal OUT2 is connected to a gate of the second power semiconductor element 32. Since a threshold voltage Vth2 of the second power semiconductor element 32 is lower than a threshold voltage Vth1 of the first power semiconductor element 31, the second power semiconductor element 32 is more likely to malfunction due to floating of the gate voltage than the first power semiconductor element 31.

In the first preferred embodiment, the first power semiconductor element 31 is an insulated gate bipolar transistor (IGBT) made of silicon (Si), and the second power semiconductor element 32 is a metal oxide semiconductor field effect transistor (MOSFET) made of silicon carbide (SiC).

However, the first power semiconductor element 31 and the second power semiconductor element 32 are not limited thereto, and for example, at least one of the first power semiconductor element 31 and the second power semiconductor element 32 may be an IGBT or a MOSFET. Note that, in the present specification, for example, at least one of A, B, C,. and Z means any one of all combinations of one or more elements extracted from the group of A, B, C, . . . , and Z.

In addition, at least one of the first power semiconductor element 31 and the second power semiconductor element 32 may be made of Si or SiC. Instead of this SiC, another wide bandgap semiconductor such as gallium nitride (GaN), gallium oxide (Ga₂O₃), or diamond may be used. In a case where at least one of the first power semiconductor element 31 and the second power semiconductor element 32 is made of a wide band gap semiconductor, it is possible to stably operate the semiconductor device at a high temperature and at a high voltage, increase the switching speed, and downsize the semiconductor device.

The second power semiconductor element 32 is connected in parallel with the first power semiconductor element 31. The first power semiconductor element 31 and the second power semiconductor element 32 may constitute an arm of an inverter apparatus that drives an inductive load such as a motor, for example. The inverter apparatus here includes, for example, a half-bridge inverter apparatus, a full-bridge inverter apparatus, a three-phase inverter apparatus, and the like.

For example, the first power semiconductor element 31 and the second power semiconductor element 32 may constitute an upper arm. In addition, a collector of the first power semiconductor element 31 and a drain of the second power semiconductor element 32 may be connected to a power supply (not illustrated), and an emitter of the first power semiconductor element 31 and a source of the second power semiconductor element 32 may be connected to a lower arm and an inductive load (not illustrated). The lower arm may include two power semiconductor elements connected in parallel, similarly to the first power semiconductor element 31 and the second power semiconductor element 32.

The first output pre-stage circuit 1 generates a first input correspondence signal on the basis of an input signal of the input terminal IN. In the first preferred embodiment, the first output pre-stage circuit 1 is a NOT circuit (inverter), and generates the first input correspondence signal by inverting the level of the input signal. That is, the first output pre-stage circuit 1 outputs a first input correspondence signal at the low level in a case where the input signal is at the high level, and outputs a first input correspondence signal at the high level in a case where the input signal is at the low level. In the first preferred embodiment, the low level corresponds to a reference voltage (GND) connected to the semiconductor element driving circuit IC, and the high level corresponds to a power supply voltage (VCC) connected to the semiconductor element driving circuit IC.

The first output circuit including the semiconductor elements 2 and 3 drives the first power semiconductor element 31 via the first output terminal OUT1 on the basis of the first input correspondence signal from the first output pre-stage circuit 1.

After the input signal of the input terminal IN becomes at the high level, the semiconductor element 2 of the first output circuit charges the gate capacitance of the first power semiconductor element 31. That is, as illustrated in FIG. 2, when the input signal of the input terminal IN becomes at the high level, the voltage of the first output terminal OUT1 becomes higher than the threshold voltage Vth1, and the first power semiconductor element 31 is turned on.

On the other hand, after the input signal of the input terminal IN becomes at the low level, the semiconductor element 3 of the first output circuit discharges the gate capacitance of the first power semiconductor element 31. That is, as illustrated in FIG. 2, when the input signal of the input terminal IN becomes at the low level, the voltage of the first output terminal OUT1 becomes lower than the threshold voltage Vth1, and the first power semiconductor element 31 is turned off.

Note that, in the first preferred embodiment, the semiconductor elements 2 and 3 are a P-type MOSFET (PMOS) and an N-type MOSFET (NMOS), respectively, but are not limited thereto.

When the first cutoff semiconductor element 4 is turned on, the first cutoff semiconductor element 4 reduces the impedance between the first output terminal OUT1 and the ground (GND) to reduce the voltage of the first output terminal OUT1, thereby suppressing floating of the gate voltage of the first power semiconductor element 31. In the first preferred embodiment, the first cutoff semiconductor element 4 is an NMOS, but is not limited thereto.

The second output pre-stage circuit 5, the second output circuit including the semiconductor elements 6 and 7, and the second cutoff semiconductor element 8 are configured similarly to the first output pre-stage circuit 1, the first output circuit including the semiconductor elements 2 and 3, and the first cutoff semiconductor element 4. That is, the second output pre-stage circuit 5 generates a second input correspondence signal on the basis of the input signal, and the second output circuit drives the second power semiconductor element 32 via the second output terminal OUT2 on the basis of the second input correspondence signal from the second output pre-stage circuit 5. When the second cutoff semiconductor element 8 is turned on, the second cutoff semiconductor element 8 reduces the impedance between the second output terminal OUT2 and the ground (GND) to reduce the voltage of the second output terminal OUT2, thereby suppressing gate floating of the second power semiconductor element 32.

If the first power semiconductor element 31 and the second power semiconductor element 32 are not connected to the first output terminal OUT1 and the second output terminal OUT2, respectively, the signal waveforms at the first output terminal OUT1 and the second output terminal OUT2 are rectangular waves similarly to the signal waveform at the input terminal IN. When the first power semiconductor element 31 and the second power semiconductor element 32 are connected to the first output terminal OUT1 and the second output terminal OUT2, respectively, as illustrated in FIG. 2, the signal waveforms at the first output terminal OUT1 and the second output terminal OUT2 have gentler changes in rise and fall per time than the signal waveform of the rectangular wave at the input terminal IN. Note that, in the following description, for convenience of explanation, a change in rise per time and a change in fall per time may be referred to as a rising change and a falling change, respectively.

The degree to which the rising change and the falling change become gentle in the signal waveform at the first output terminal OUT1 is determined by the on-resistance of the first output circuit and the gate capacitance of the first power semiconductor element 31. Similarly, the degree to which the rising change and the falling change become gentle in the signal waveform at the second output terminal OUT2 is determined by the on-resistance of the second output circuit and the gate capacitance of the second power semiconductor element 32.

In the first preferred embodiment, by the on-resistance and the gate capacitance being adjusted, the rising change of the signal waveform at the second output terminal OUT2 is gentler than the rising change of the signal waveform at the first output terminal OUT1. In addition, by the on-resistance and the gate capacitance being adjusted, the falling change of the signal waveform at the second output terminal OUT2 is steeper than the falling change of the signal waveform at the first output terminal OUT1. Accordingly, the second power semiconductor element 32 having a low threshold voltage can operate without substantially contributing to switching, which makes it possible to reduce the conduction loss.

Note that, in the first preferred embodiment, the second power semiconductor element 32 has a chip area smaller than that of the first power semiconductor element 31. According to such a configuration, the falling change of the signal waveform at the second output terminal OUT2 can be made steeper than the falling change of the signal waveform at the first output terminal OUT1. Therefore, it is possible to easily implement the operation of the second power semiconductor element 32 having a low threshold voltage without substantially contributing to switching, which makes it possible to easily reduce the conduction loss.

Note that, for easy understanding of the above description, FIG. 2 does not reflect floating of the gate voltages of the first output terminal OUT1 and the second output terminal OUT2, reduction of the gate voltage of the first output terminal OUT1 due to turning on of the first cutoff semiconductor element 4, and the like.

The cutoff pre-stage circuit 9 in FIG. 1 is connected to gates of the first cutoff semiconductor element 4 and the second cutoff semiconductor element 8. In the first preferred embodiment, the cutoff pre-stage circuit 9 is a NOT circuit (inverter), inverts the level of a signal from the cutoff control circuit 10, and outputs the inverted signal to the gates of the first cutoff semiconductor element 4 and the second cutoff semiconductor element 8.

The cutoff control circuit 10 controls the first cutoff semiconductor element 4 and the second cutoff semiconductor element 8 via the cutoff pre-stage circuit 9 on the basis of the input signal of the input terminal IN and the voltage of the first output terminal OUT1. Hereinafter, the control of the cutoff control circuit 10 will be described with reference to the voltage at a connection point VG between the cutoff pre-stage circuit 9 and the gates of the first cutoff semiconductor element 4 and the second cutoff semiconductor element 8.

In a case where the input signal of the input terminal IN changes from the low level to the high level, the cutoff control circuit 10 outputs a signal at the low level from the cutoff pre-stage circuit 9 to the gates of the first cutoff semiconductor element 4 and the second cutoff semiconductor element 8 as in the voltage at the connection point VG at a time point t1 in FIG. 2. As a result, the cutoff control circuit 10 turns off the first cutoff semiconductor element 4 and the second cutoff semiconductor element 8 via the cutoff pre-stage circuit 9.

On the other hand, in a case where the input signal of the input terminal IN is at the low level and the voltage of the first output terminal OUT1 becomes lower than a predetermined value Vgt, the cutoff control circuit 10 outputs a signal at the high level from the cutoff pre-stage circuit 9 to the gates of the first cutoff semiconductor element 4 and the second cutoff semiconductor element 8, as in the voltage at the connection point VG at a time point t2 in FIG. 2. As a result, the cutoff control circuit 10 turns on the first cutoff semiconductor element 4 and the second cutoff semiconductor element 8 via the cutoff pre-stage circuit 9.

In the first preferred embodiment, the time point t2 at which the first cutoff semiconductor element 4 and the second cutoff semiconductor element 8 are turned on is sufficiently later than time points at which the voltages of the first output terminal OUT1 and the second output terminal OUT2 become equal to or lower than the threshold voltages Vth1 and Vth2. As described above, if the first cutoff semiconductor element 4 and the second cutoff semiconductor element 8 are turned on sufficiently later than the switching of the first power semiconductor element 31 and the second power semiconductor element 32, it is possible to suppress noise radiated from the semiconductor device to the outside.

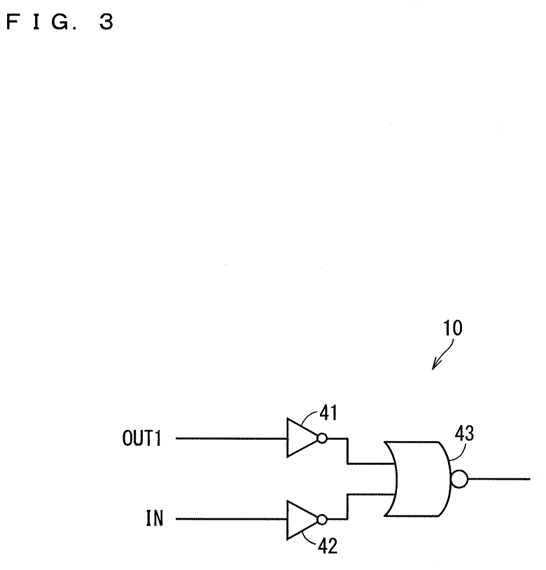

FIGS. 3 to 6 are circuit diagrams each illustrating a configuration example of the cutoff control circuit 10.

As illustrated in FIG. 3, the cutoff control circuit 10 may include NOT circuits 41 and 42, and a NAND circuit 43 whose inputs are connected to the NOT circuits 41 and 42. Note that the value of a threshold voltage of the NOT circuit 41 to which a signal of the first output terminal OUT1 is input is the value Vgt in FIG. 2. In a case where the input signal of the input terminal IN is at the low level and the voltage of the first output terminal OUT1 is lower than the value Vgt, the cutoff control circuit 10 configured as described above outputs a signal at the low level, so that the voltage at the connection point VG at the time point t2 in FIG. 2 can be set to the high level.

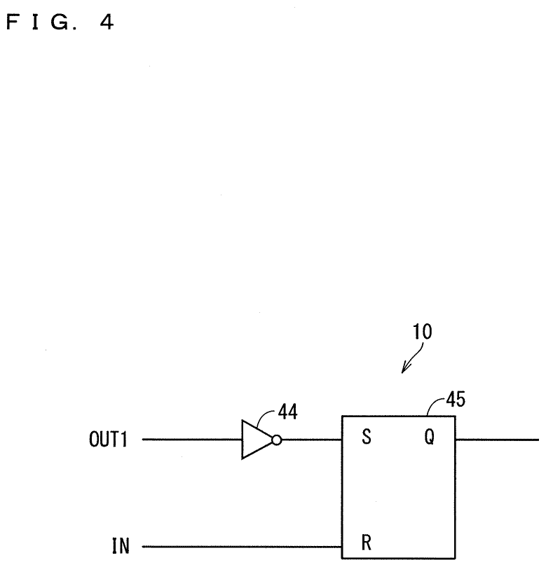

As illustrated in FIG. 4, the cutoff control circuit 10 may include a NOT circuit 44 and an SR-FF circuit 45 in which the NOT circuit 44 is connected to an S terminal and the input signal of the input terminal IN is input to an R terminal. According to the configuration of FIG. 3, the cutoff control circuit 10 can be implemented with a simple circuit configuration, but in a case where the gate voltage floats and the voltage of the first output terminal OUT1 becomes equal to or higher than the value Vgt, the first cutoff semiconductor element 4 and the second cutoff semiconductor element 8 cannot be turned on. Meanwhile, according to the configuration of FIG. 4, even if the gate voltage floats and the voltage of the first output terminal OUT1 becomes equal to or higher than the value Vgt, the first cutoff semiconductor element 4 and the second cutoff semiconductor element 8 can be turned on.

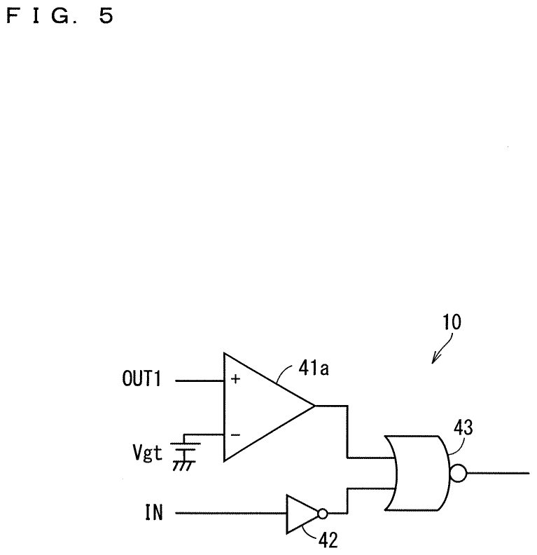

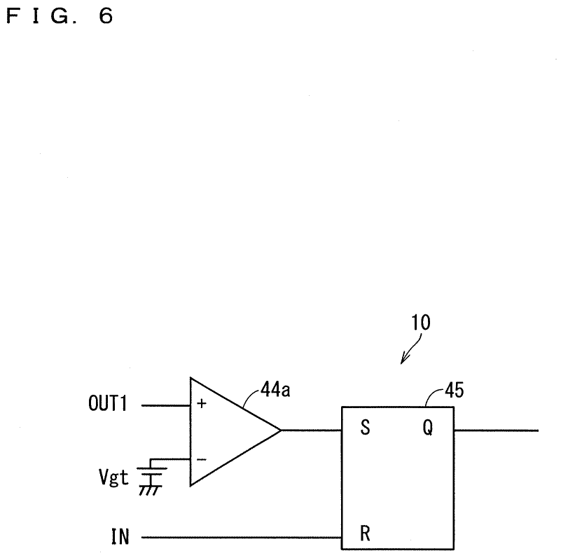

As illustrated in FIGS. 5 and 6, the cutoff control circuit 10 may have a configuration in which the NOT circuits 41 and 44 in the configurations of FIGS. 3 and 4 are replaced with comparators 41a and 44a. According to such a configuration, although the circuit scale slightly increases depending on the response speed of the comparators, it is possible to reduce the influence of changes in the power supply voltage and the temperature because Vgt serves as a reference voltage of the comparators.

Note that the configuration of the cutoff control circuit 10 is not limited to the configurations in FIGS. 3 to 6, and other configurations may be used. An appropriate configuration according to an application is applied to the configuration of the cutoff control circuit 10.

### Summary of First Preferred Embodiment

According to the semiconductor element driving circuit IC according to the first preferred embodiment as described above, the cutoff control circuit 10 turns on the first cutoff semiconductor element 4 and the second cutoff semiconductor element 8 in a case where an input signal of the input terminal IN is at the low level and the voltage of the first output terminal OUT1 is lower than the value Vgt. According to such a configuration, it is possible to suppress floating of the gate voltages in the first power semiconductor element 31 and the second power semiconductor element 32, which makes it possible to suppress malfunction of the first power semiconductor element 31 and the second power semiconductor element 32.

Furthermore, in the first preferred embodiment, one cutoff pre-stage circuit 9 and one cutoff control circuit 10 control both the first cutoff semiconductor element 4 and the second cutoff semiconductor element 8. Therefore, it is possible to reduce the circuit scale as compared with a configuration in which each of the first cutoff semiconductor element 4 and the second cutoff semiconductor element 8 is provided with a cutoff pre-stage circuit and a cutoff control circuit.

Furthermore, in general, as the value Vgt decreases, the circuit scale of the cutoff control circuit 10 that determines whether the voltage of the first output terminal OUT1 is lower than the value Vgt increases. On the other hand, in the first preferred embodiment, the cutoff control circuit 10 controls the first cutoff semiconductor element 4 and the second cutoff semiconductor element 8 on the basis of the input and output on the first output circuit side that controls the first power semiconductor element 31 having the high threshold voltage Vth1.

Therefore, it is possible to make the value Vgt of the cutoff control circuit 10 higher than the value Vgt of a related circuit that controls the first cutoff semiconductor element 4 and the second cutoff semiconductor element 8 on the basis of the input and output on the second output circuit side that controls the second power semiconductor element 32 having the low threshold voltage Vth2. As a result, according to the first preferred embodiment, it is possible to reduce the circuit scale of the cutoff control circuit 10 and, consequently, to reduce the circuit scale of the semiconductor element driving circuit IC.

Note that, in the configuration of the first preferred embodiment in which the cutoff control circuit 10 that controls both the first cutoff semiconductor element 4 and the second cutoff semiconductor element 8 is provided, the timing of turning on the second cutoff semiconductor element 8 may be later than that of a configuration in which two cutoff control circuits that respectively control the first cutoff semiconductor element 4 and the second cutoff semiconductor element 8 are provided. However, the delay in the timing causes no problems because it is not assumed that the opposing arm performs switching before the voltage of the first output terminal OUT1 becomes sufficiently low.

Furthermore, in a case where the size of the semiconductor element 7 of the second output circuit is sufficiently large, it is possible to suppress floating of the gate voltage of the second power semiconductor element 32. However, in such a case, there is a problem that the current at the time of discharging the voltage of the second output terminal OUT2 increases, the off-operation of the second power semiconductor element 32 becomes fast, and thus the noise radiated from the semiconductor device to the outside increases. On the other hand, according to the first preferred embodiment, it is possible to suppress floating of the gate voltage of the second power semiconductor element 32 without increasing the size of the semiconductor element 7 of the second output circuit, which makes it possible to prevent the noise from increasing.

### Second Preferred Embodiment

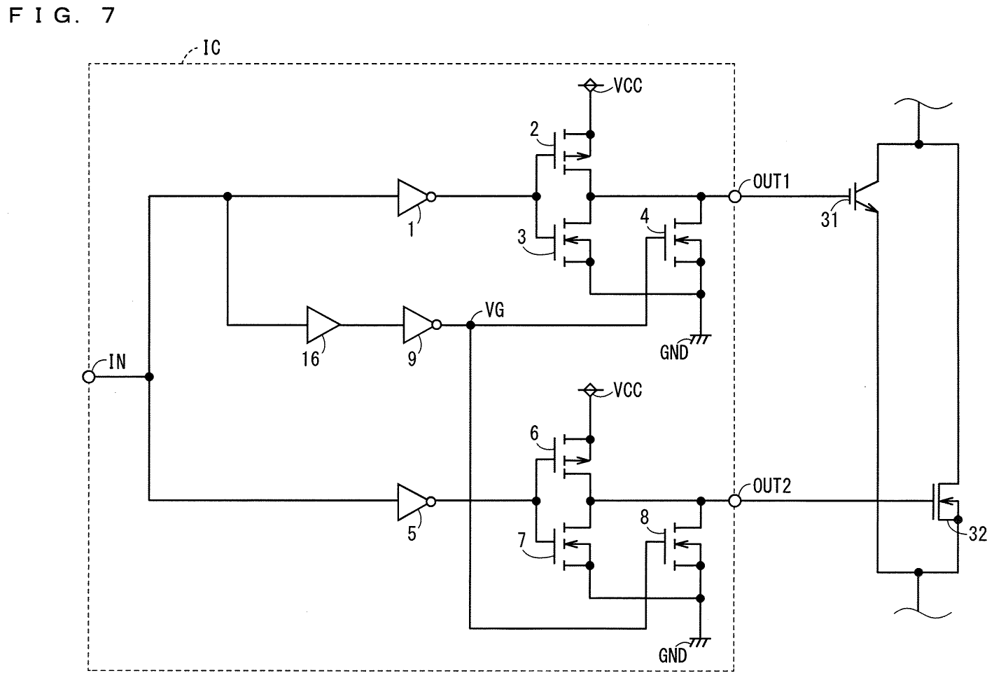

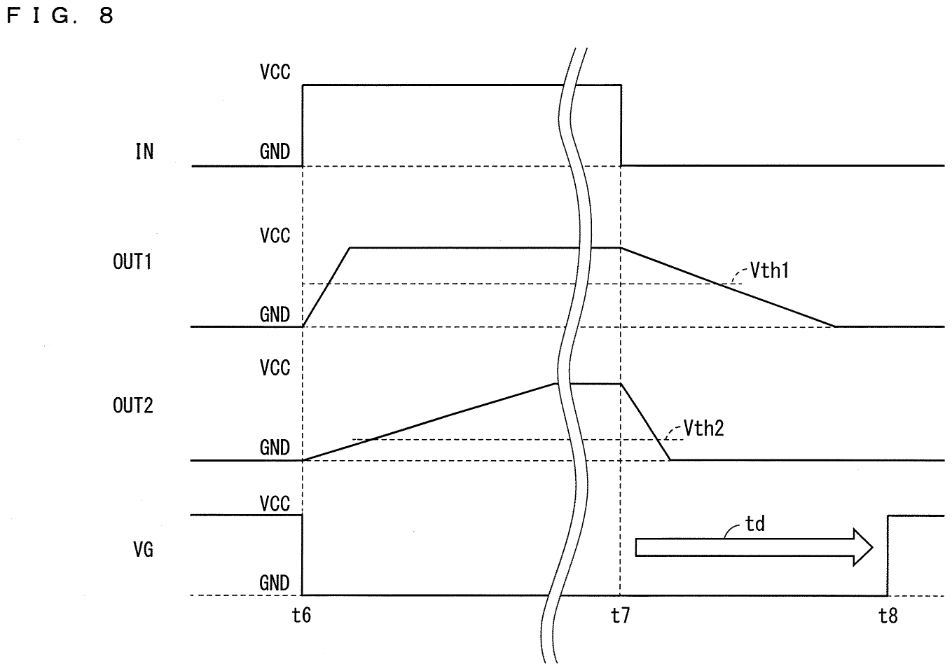

FIG. 7 is a circuit diagram illustrating a configuration of a semiconductor element driving circuit IC according to the second preferred embodiment, and FIG. 8 is a timing chart illustrating an outline of operation of the semiconductor element driving circuit IC.

The configuration of FIG. 7 is similar to a configuration in which the cutoff control circuit 10 in the configuration of FIG. 1 is replaced with a delay buffer 16. Note that an input terminal IN, a first output terminal OUT1, a second output terminal OUT2, a first output pre-stage circuit 1, a first output circuit including semiconductor elements 2 and 3, a first cutoff semiconductor element 4, a second output pre-stage circuit 5, a second output circuit including semiconductor elements 6 and 7, a second cutoff semiconductor element 8, and a cutoff pre-stage circuit 9 are similar to those of the first preferred embodiment.

The delay buffer 16 is configured to be able to turn on the first cutoff semiconductor element 4 and the second cutoff semiconductor element 8 by outputting a delay signal, which is a signal whose falling time point is delayed from a falling time point of an input signal, to the first cutoff semiconductor element 4 and the second cutoff semiconductor element 8 via the cutoff pre-stage circuit 9.

In the second preferred embodiment, the delay buffer 16 outputs a signal at the low level to the cutoff pre-stage circuit 9 at a time point t8 delayed by a time td from a falling time point t7 of an input signal of the input terminal IN in FIG. 8, so that the voltage at a connection point VG becomes at the high level. Therefore, at the time point t8, the first cutoff semiconductor element 4 and the second cutoff semiconductor element 8 are turned on.

Note that the delay by the delay buffer 16 is preferably adjusted such that the first cutoff semiconductor element 4 and the second cutoff semiconductor element 8 are turned on sufficiently later than the switching of a first power semiconductor element 31 and a second power semiconductor element 32. According to such a configuration, it is possible to suppress noise radiated from the semiconductor device to the outside.

In the second preferred embodiment, the delay signal is a signal in which the falling time point is delayed from the falling time point of the input signal, but the rising time point is not delayed from a rising time point of the input signal. Therefore, the delay buffer 16 outputs a signal at the high level to the cutoff pre-stage circuit 9 at a rising time point t6 of the input signal of the input terminal IN in FIG. 8, so that the voltage at the connection point VG becomes at the low level.

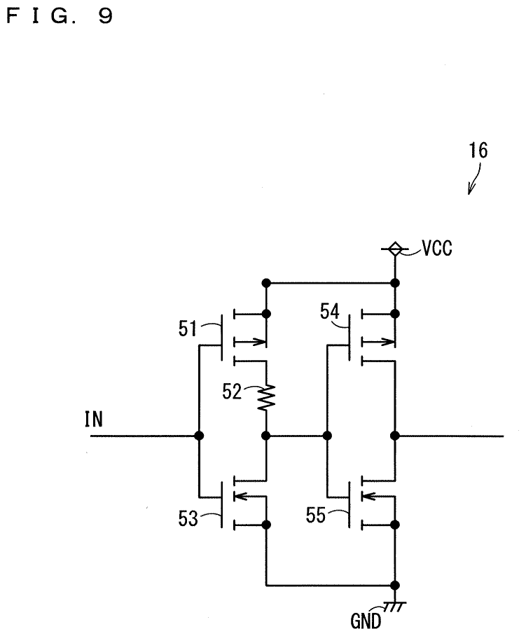

FIG. 9 is a circuit diagram illustrating a configuration example of the delay buffer 16. As illustrated in FIG. 9, the delay buffer 16 may include a PMOS 51, a PMOS 54, a resistor 52, an NMOS 53, and an NMOS 55. The PMOS 51, the resistor 52, and the NMOS 53 are connected in series in this order from a power supply voltage (VCC) to a reference voltage (GND) to constitute a first NOT circuit. The PMOS 54 and the NMOS 55 are connected in series in this order from the power supply voltage (VCC) to the reference voltage (GND) to constitute a second NOT circuit. A connection point between the resistor 52 and the NMOS 53 is connected to gates of the PMOS 54 and the NMOS 55, and the first NOT circuit and the second NOT circuit are substantially connected in series.

The resistor 52 connected to the PMOS 51 delays the rising time point of the output signal of the first NOT circuit from the falling time point of the input signal. The second NOT circuit inverts the output signal of the first NOT circuit. Therefore, the delay buffer 16 configured as described above can output a signal at the low level to the cutoff pre-stage circuit 9 at the time point t8 delayed by the time td from the falling time point t7 of the input signal of the input terminal IN in FIG. 8.

Note that the configuration of the delay buffer 16 is not limited to the configuration of FIG. 9, and other configurations may be used. An appropriate configuration according to an application is applied to the configuration of the delay buffer 16.

### Summary of Second Preferred Embodiment

The semiconductor element driving circuit IC according to the second preferred embodiment as described above is configured to be able to turn on the first cutoff semiconductor element 4 and the second cutoff semiconductor element 8 by outputting a delay signal, which is a signal whose falling time point is delayed from a falling time point of an input signal, to the first cutoff semiconductor element 4 and the second cutoff semiconductor element 8 via the cutoff pre-stage circuit 9. According to such a configuration, as in the first preferred embodiment, it is possible to suppress malfunction of the first power semiconductor element 31 and the second power semiconductor element 32.

Furthermore, in the second preferred embodiment, one cutoff pre-stage circuit 9 and one delay buffer 16 control both the first cutoff semiconductor element 4 and the second cutoff semiconductor element 8. Therefore, it is possible to reduce the circuit scale as compared with a configuration in which each of the first cutoff semiconductor element 4 and the second cutoff semiconductor element 8 is provided with a cutoff pre-stage circuit and a delay buffer.

### Third Preferred Embodiment

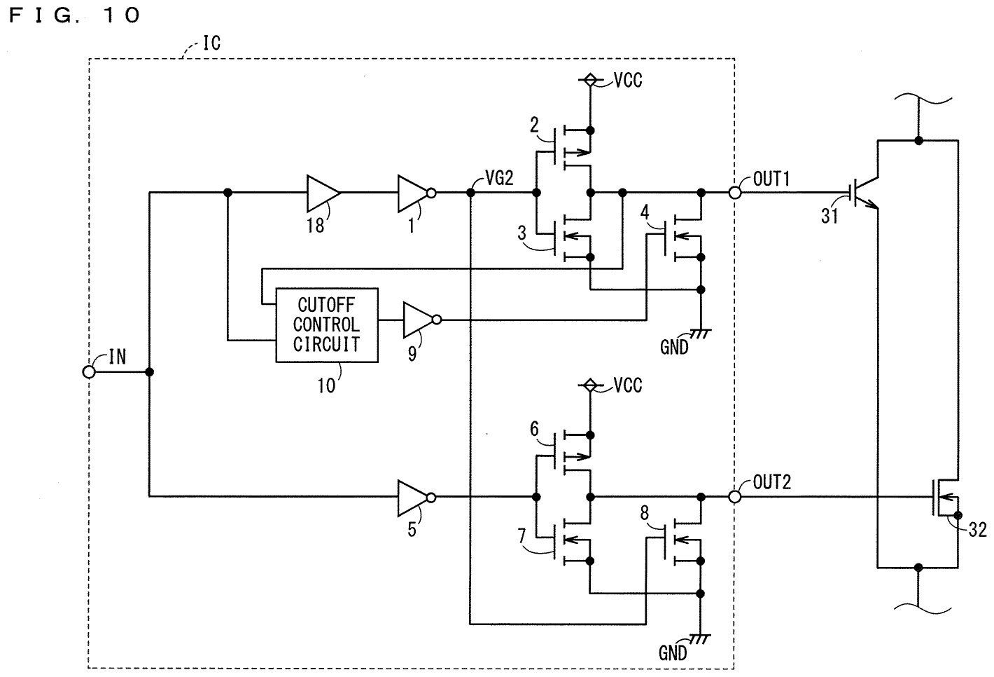

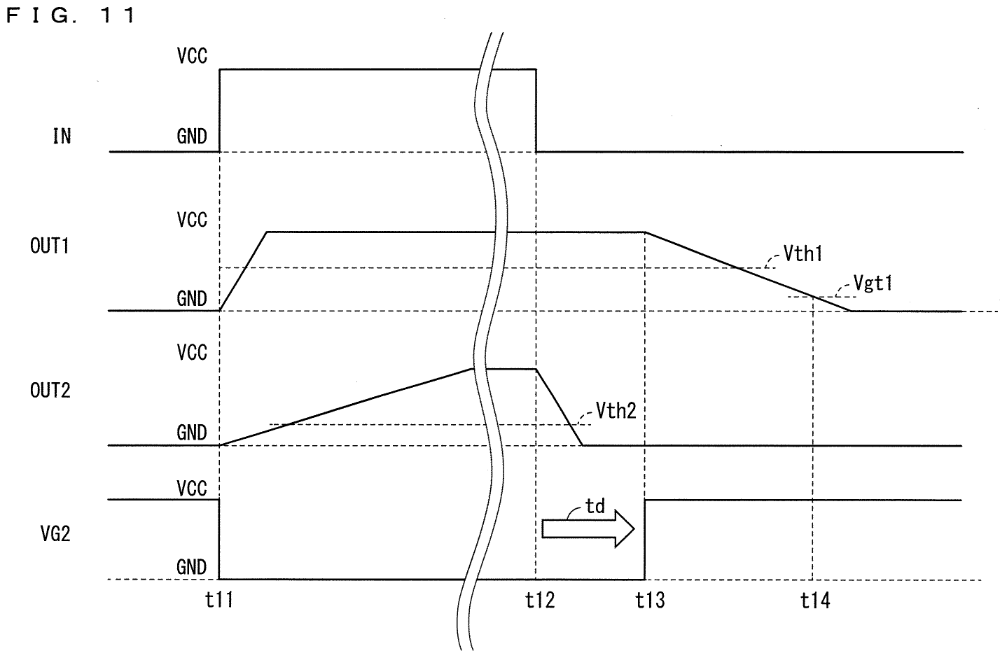

FIG. 10 is a circuit diagram illustrating a configuration of a semiconductor element driving circuit IC according to the third preferred embodiment, and FIG. 11 is a timing chart illustrating an outline of operation of the semiconductor element driving circuit IC.

In the configuration of FIG. 10, a delay buffer 18 is added to the configuration of FIG. 1. Note that an input terminal IN, a first output terminal OUT1, and a second output terminal OUT2 are similar to those of the first preferred embodiment.

The delay buffer 18 is substantially similar to the delay buffer 16 according to second preferred embodiment, and generates a delay signal, which is a signal whose falling time point is delayed from a falling time point of an input signal of the input terminal IN.

A first output pre-stage circuit 1 generates a delay correspondence signal on the basis of the delay signal from the delay buffer 18. In the third preferred embodiment, the first output pre-stage circuit 1 is a NOT circuit (inverter), and generates the delay correspondence signal by inverting the level of the delay signal.

A first output circuit including semiconductor elements 2 and 3 is substantially similar to the first output circuit according to the first preferred embodiment, and drives a first power semiconductor element 31 via the first output terminal OUT1 on the basis of the delay correspondence signal from the first output pre-stage circuit 1.

A first cutoff semiconductor element 4 is similar to the first cutoff semiconductor element 4 according to the first preferred embodiment. A second output pre-stage circuit 5 is substantially similar to the second output pre-stage circuit 5 according to the first preferred embodiment, and generates an input correspondence signal on the basis of the input signal of the input terminal IN. A second output circuit including semiconductor elements 6 and 7 is substantially similar to the second output circuit according to the first preferred embodiment, and drives a second power semiconductor element 32 via the second output terminal OUT2 on the basis of the input correspondence signal from the second output pre-stage circuit 5.

A second cutoff semiconductor element 8 is substantially similar to the second cutoff semiconductor element 8 according to the first preferred embodiment, and reduces the voltage of the second output terminal OUT2 when turned on. However, in the third preferred embodiment, the second cutoff semiconductor element 8 is turned on based on the delay correspondence signal from the first output pre-stage circuit 1.

In the third preferred embodiment, the delay buffer 18 outputs a signal at the low level to the first output pre-stage circuit 1 at a time point t13 delayed by a time td from a falling time point t12 of the input signal of the input terminal IN in FIG. 11, and thus the voltage of the first output terminal OUT1 starts to fall. Furthermore, at the time point t13, the voltage at a connection point VG2 between the first output pre-stage circuit 1 and the second cutoff semiconductor element 8 becomes at the high level, and thus the second cutoff semiconductor element 8 is turned on.

Note that the delay by the delay buffer 18 is preferably adjusted such that the second cutoff semiconductor element 8 is turned on sufficiently later than the switching of the second power semiconductor element 32. According to such a configuration, it is possible to suppress noise radiated from the semiconductor device to the outside.

In the third preferred embodiment, the delay signal is a signal in which the falling time point is delayed from the falling point of the input signal, but the rising time point is not delayed from a rising point of the input signal. Therefore, the delay buffer 18 outputs a signal at the high level to the first output pre-stage circuit 1 at a rising time point t11 of the input signal of the input terminal IN in FIG. 11, so that the voltage at the connection point VG2 becomes at the low level.

A cutoff pre-stage circuit 9 in FIG. 10 is substantially similar to the cutoff pre-stage circuit 9 according to the first preferred embodiment, and is connected to a gate of the first cutoff semiconductor element 4. However, in the third preferred embodiment, the cutoff pre-stage circuit 9 is not connected to a gate of the second cutoff semiconductor element 8.

A cutoff control circuit 10 is substantially similar to the cutoff control circuit 10 according to the first preferred embodiment, and turns on the first cutoff semiconductor element 4 via the cutoff pre-stage circuit 9 in a case where the input signal is at the low level and the voltage of the first output terminal OUT1 is lower than a predetermined value Vgt. That is, at a time point t14 in FIG. 11, the cutoff control circuit 10 turns on the first cutoff semiconductor element 4 via the cutoff pre-stage circuit 9. However, in the third preferred embodiment, the cutoff control circuit 10 does not turn on the second cutoff semiconductor element 8 via the cutoff pre-stage circuit 9.

### Summary of Third Preferred Embodiment

According to the semiconductor element driving circuit IC according to the third preferred embodiment as described above, the cutoff control circuit 10 turns on the first cutoff semiconductor element 4 in a case where the input signal of the input terminal IN is at the low level and the voltage of the first output terminal OUT1 is lower than the value Vgt. Furthermore, the second cutoff semiconductor element 8 is turned on based on the delay correspondence signal from the first output pre-stage circuit 1. According to such a configuration, as in the first preferred embodiment, it is possible to suppress malfunction of the first power semiconductor element 31 and the second power semiconductor element 32.

Furthermore, in the third preferred embodiment, the delay buffer 18 and the first output pre-stage circuit 1 control the second cutoff semiconductor element 8. Therefore, it is possible to reduce the circuit scale as compared with a configuration in which the second cutoff semiconductor element 8 is provided with a cutoff pre-stage circuit and a cutoff control circuit.

### Fourth Preferred Embodiment

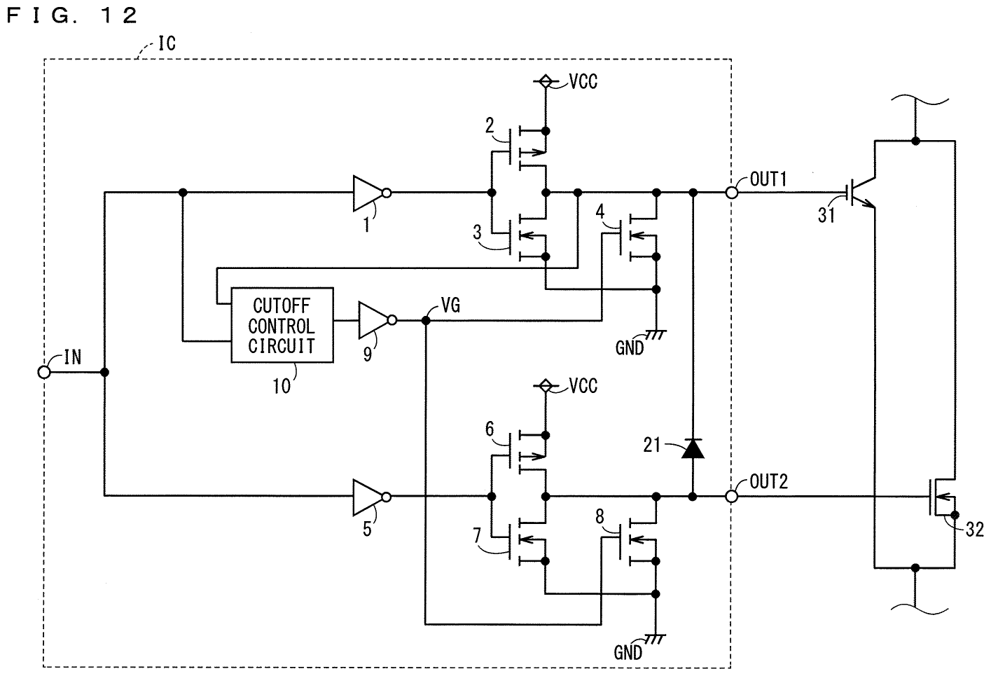

FIG. 12 is a circuit diagram illustrating a configuration of a semiconductor element driving circuit IC according to the fourth preferred embodiment. Note that a timing chart illustrating an outline of operation of the semiconductor element driving circuit IC is substantially similar to the timing chart of FIG. 2.

The configuration of FIG. 12 is similar to a configuration in which a diode 21 is added to the configuration of FIG. 1. The diode 21 has a cathode connected to a first output terminal OUT1 and an anode connected to a second output terminal OUT2. Note that the diode may be a Schottky barrier diode (SBD) or a PN junction diode (PND).

According to the semiconductor element driving circuit IC according to the fourth preferred embodiment as described above, the voltage of the second output terminal OUT2 can be made lower than the voltage of the first output terminal OUT1. As a result, floating of the gate voltage of a second power semiconductor element 32 can be suppressed more than floating of the gate voltage of a first power semiconductor element 31, so that it is possible to suppress malfunction of the second power semiconductor element 32 having a low threshold voltage Vth2.

Note that, although the example has been described above in which the diode 21 according to the fourth preferred embodiment is applied to the configuration of FIG. 1 of the first preferred embodiment, the diode 21 may be applied to the configuration of the second or third preferred embodiment.

Note that, in the present disclosure in English, ‘a’ and ‘an’ mean one or more. Thus, ‘a’, ‘an’, ‘one or more’ and ‘at least one’ can be used interchangeably.

Note that the preferred embodiments and the modifications can be freely combined, and the preferred embodiments and the modifications can be appropriately modified or omitted.

Hereinafter, various aspects of the present disclosure will be collectively described as appendixes.

### Appendix 1

A semiconductor element driving circuit comprising:
an input terminal;
a first output terminal to which a first power semiconductor element is connected;
a second output terminal to which a second power semiconductor element connected in parallel with the first power semiconductor element and having a lower threshold voltage than the first power semiconductor element is connected;
a first output pre-stage circuit that generates a first input correspondence signal on the basis of an input signal of the input terminal;
a first output circuit that drives the first power semiconductor element via the first output terminal on the basis of the first input correspondence signal;
a first cutoff semiconductor element that reduces a voltage of the first output terminal when turned on;
a second output pre-stage circuit that generates a second input correspondence signal on the basis of the input signal;
a second output circuit that drives the second power semiconductor element via the second output terminal on the basis of the second input correspondence signal;
a second cutoff semiconductor element that reduces a voltage of the second output terminal when turned on;
a cutoff pre-stage circuit that is connected to the first cutoff semiconductor element and the second cutoff semiconductor element; and
a cutoff control circuit that turns on the first cutoff semiconductor element and the second cutoff semiconductor element via the cutoff pre-stage circuit in a case where the input signal is at a low level and the voltage of the first output terminal is lower than a predetermined value.

### Appendix 2

A semiconductor element driving circuit comprising:
an input terminal;
a first output terminal to which a first power semiconductor element is connected;
a second output terminal to which a second power semiconductor element connected in parallel with the first power semiconductor element and having a lower threshold voltage than the first power semiconductor element is connected;
a first output pre-stage circuit that generates a first input correspondence signal on the basis of an input signal of the input terminal;
a first output circuit that drives the first power semiconductor element via the first output terminal on the basis of the first input correspondence signal;
a first cutoff semiconductor element that reduces a voltage of the first output terminal when turned on;
a second output pre-stage circuit that generates a second input correspondence signal on the basis of the input signal;
a second output circuit that drives the second power semiconductor element via the second output terminal on the basis of the second input correspondence signal;
a second cutoff semiconductor element that reduces a voltage of the second output terminal when turned on;
a cutoff pre-stage circuit that is connected to the first cutoff semiconductor element and the second cutoff semiconductor element; and
a delay buffer that is capable of turning on the first cutoff semiconductor element and the second cutoff semiconductor element by outputting a delay signal, which is a signal whose falling time point is delayed from a falling time point of the input signal, to the first cutoff semiconductor element and the second cutoff semiconductor element via the cutoff pre-stage circuit.

### Appendix 3

A semiconductor element driving circuit comprising:
an input terminal;
a first output terminal to which a first power semiconductor element is connected;
a second output terminal to which a second power semiconductor element connected in parallel with the first power semiconductor element and having a lower threshold voltage than the first power semiconductor element is connected;
a delay buffer that generates a delay signal, which is a signal whose falling time point is delayed from a falling time point of an input signal of the input terminal;
a first output pre-stage circuit that generates a delay correspondence signal on the basis of the delay signal;
a first output circuit that drives the first power semiconductor element via the first output terminal on the basis of the delay correspondence signal;
a first cutoff semiconductor element that reduces a voltage of the first output terminal when turned on;
a second output pre-stage circuit that generates an input correspondence signal on the basis of the input signal;
a second output circuit that drives the second power semiconductor element via the second output terminal on the basis of the input correspondence signal;
a second cutoff semiconductor element that is turned on based on the delay correspondence signal and reduces a voltage of the second output terminal when turned on;
a cutoff pre-stage circuit that is connected to the first cutoff semiconductor element; and
a cutoff control circuit that turns on the first cutoff semiconductor element via the cutoff pre-stage circuit in a case where the input signal is at a low level and the voltage of the first output terminal is lower than a predetermined value.

### Appendix 4

The semiconductor element driving circuit according to any one of Appendixes 1 to 3, further comprising
a diode having a cathode connected to the first output terminal and an anode connected to the second output terminal.

### Appendix 5

The semiconductor element driving circuit according to any one of Appendixes 1 to 4, wherein the second power semiconductor element has a chip area smaller than a chip area of the first power semiconductor element.

### Appendix 6

The semiconductor element driving circuit according to any one of Appendixes 1 to 5, wherein
the first power semiconductor element is an IGBT made of silicon, and
the second power semiconductor element is a MOSFET made of silicon carbide.

While the disclosure has been shown and described in detail, the foregoing description is in all aspects illustrative and not restrictive. It is therefore understood that numerous modifications and variations can be devised.

What is claimed is:

1. A semiconductor element driving circuit comprising:
an input terminal;
a first output terminal to which a first power semiconductor element is connected;
a second output terminal to which a second power semiconductor element connected in parallel with the first power semiconductor element and having a lower threshold voltage than the first power semiconductor element is connected;
a first output pre-stage circuit that generates a first input correspondence signal on the basis of an input signal of the input terminal;
a first output circuit that drives the first power semiconductor element via the first output terminal on the basis of the first input correspondence signal;
a first cutoff semiconductor element that reduces a voltage of the first output terminal when turned on;
a second output pre-stage circuit that generates a second input correspondence signal on the basis of the input signal;
a second output circuit that drives the second power semiconductor element via the second output terminal on the basis of the second input correspondence signal;
a second cutoff semiconductor element that reduces a voltage of the second output terminal when turned on;
a cutoff pre-stage circuit that is connected to the first cutoff semiconductor element and the second cutoff semiconductor element; and
a cutoff control circuit that turns on the first cutoff semiconductor element and the second cutoff semiconductor element via the cutoff pre-stage circuit in a case where the input signal is at a low level and the voltage of the first output terminal is lower than a predetermined value.

2. A semiconductor element driving circuit comprising:
an input terminal;
a first output terminal to which a first power semiconductor element is connected;
a second output terminal to which a second power semiconductor element connected in parallel with the first power semiconductor element and having a lower threshold voltage than the first power semiconductor element is connected;
a first output pre-stage circuit that generates a first input correspondence signal on the basis of an input signal of the input terminal;
a first output circuit that drives the first power semiconductor element via the first output terminal on the basis of the first input correspondence signal;
a first cutoff semiconductor element that reduces a voltage of the first output terminal when turned on;
a second output pre-stage circuit that generates a second input correspondence signal on the basis of the input signal;
a second output circuit that drives the second power semiconductor element via the second output terminal on the basis of the second input correspondence signal;
a second cutoff semiconductor element that reduces a voltage of the second output terminal when turned on;
a cutoff pre-stage circuit that is connected to the first cutoff semiconductor element and the second cutoff semiconductor element; and
a delay buffer that is capable of turning on the first cutoff semiconductor element and the second cutoff semiconductor element by outputting a delay signal, which is a signal whose falling time point is delayed from a falling time point of the input signal, to the first cutoff semiconductor element and the second cutoff semiconductor element via the cutoff pre-stage circuit.

3. A semiconductor element driving circuit comprising:
an input terminal;
a first output terminal to which a first power semiconductor element is connected;
a second output terminal to which a second power semiconductor element connected in parallel with the first power semiconductor element and having a lower threshold voltage than the first power semiconductor element is connected;
a delay buffer that generates a delay signal, which is a signal whose falling time point is delayed from a falling time point of an input signal of the input terminal;
a first output pre-stage circuit that generates a delay correspondence signal on the basis of the delay signal;
a first output circuit that drives the first power semiconductor element via the first output terminal on the basis of the delay correspondence signal;
a first cutoff semiconductor element that reduces a voltage of the first output terminal when turned on;
a second output pre-stage circuit that generates an input correspondence signal on the basis of the input signal;
a second output circuit that drives the second power semiconductor element via the second output terminal on the basis of the input correspondence signal;
a second cutoff semiconductor element that is turned on based on the delay correspondence signal and reduces a voltage of the second output terminal when turned on;
a cutoff pre-stage circuit that is connected to the first cutoff semiconductor element; and
a cutoff control circuit that turns on the first cutoff semiconductor element via the cutoff pre-stage circuit in a case where the input signal is at a low level and the voltage of the first output terminal is lower than a predetermined value.

4. The semiconductor element driving circuit according to claim 1, further comprising
a diode having a cathode connected to the first output terminal and an anode connected to the second output terminal.

5. The semiconductor element driving circuit according to claim 1, wherein the second power semiconductor element has a chip area smaller than a chip area of the first power semiconductor element.

6. The semiconductor element driving circuit according to claim 1, wherein
the first power semiconductor element is an IGBT made of silicon, and
the second power semiconductor element is a MOSFET made of silicon carbide.

7. The semiconductor element driving circuit according to claim 2, further comprising
a diode having a cathode connected to the first output terminal and an anode connected to the second output terminal.

8. The semiconductor element driving circuit according to claim 2, wherein the second power semiconductor element has a chip area smaller than a chip area of the first power semiconductor element.

9. The semiconductor element driving circuit according to claim 2, wherein
the first power semiconductor element is an IGBT made of silicon, and
the second power semiconductor element is a MOSFET made of silicon carbide.

10. The semiconductor element driving circuit according to claim 3, further comprising
a diode having a cathode connected to the first output terminal and an anode connected to the second output terminal.

11. The semiconductor element driving circuit according to claim 3, wherein the second power semiconductor element has a chip area smaller than a chip area of the first power semiconductor element.

12. The semiconductor element driving circuit according to claim 3, wherein
the first power semiconductor element is an IGBT made of silicon, and
the second power semiconductor element is a MOSFET made of silicon carbide.
